(19) United States
(12) Patent Application Publication
(10) Pub. No.: US 2022/0395841 A1
(43) Pub. Date: Dec. 15, 2022

(54) Micro-element Recycling Method and System

(71) Applicant: CHONGQING KONKA PHOTOELECTRIC TECHNOLOGY RESEARCH INSITUTE CO., LTD., Chongqing (CN)

(72) Inventor: CHEN HUNG-WEN, Chongqing (CN)

(21) Appl. No.: 17/431,724

(22) PCT Filed: Mar. 29, 2021
(86) PCT No.: PCT/CN2020/092423

§ 371 Date: Aug. 18, 2021

(30) Foreign Application Priority Data
May 22, 2020 (CN) 202010444384.1

(51) Int. Cl. B03C 7/12; B03C 1/26

(52) U.S. Cl. CPC B03C 7/12; B03C 1/26; B03C 2201/22; B03C 2201/20; B03C 2201/32

(57) ABSTRACT

Provided is a micro-element recycling method and system. The method includes: collecting at least one micro-element failing in transfer; applying a first acting force to the micro-element in a first direction, and applying a second acting force to the micro-element in a second direction; moving the micro-element from an initial position to a target position by means of the combined action of the first acting force and the second acting force; and recycling the micro-element located at the target position.

### CROSS-REFERENCE TO RELATED APPLICATION

The present disclosure claims priority to Chinese Patent Application No. 202010444384.1, filed to the China National Intellectual Property Administration on May 22, 2020, the disclosure of which is hereby incorporated by reference in its entirety.

### TECHNICAL FIELD

The present disclosure relates to the technical field of mass transfer, and particularly relates to a micro-element recycling method and a micro-element recycling system.

### BACKGROUND

With the development of the science and technology, the light emitting diode (LED) has become an important display element in the display screen due to the advantages of excellent stability, long service life, low power consumption, desirable color saturation, high reaction speed, strong contrast ratio, etc. Plenty of LED chips are mounted on an existing LED display panel, and in the manufacturing process of the display screen, the LED chips need to be transferred to the display back plate of the display screen from a growth substrate of the LED chips.

In order to satisfy the conversion requirement of small-size micro LED chips, various liquid assembly modes are commonly used in the related art, the micro LED chips in three colors of red, green and blue are transferred simultaneously, however, in the transfer process, part of micro LED chips fails to be transferred due to various reasons and then are mixed together in a container, so these micro LED chips are difficult to reuse, causing waste in production.

### SUMMARY

For overcoming the defects, the objective of the present disclosure is to provide a recycling method and system for a micro-element failing in liquid self-assembly transfer.

The objective of the present disclosure is achieved by the following technical solutions:

at least one micro-element failing in transfer is collected;

a first acting force is applied to the micro-element in a first direction, and applying a second acting force to the micro-element in a second direction;

the micro-element is moved from an initial position to a target position by means of the combined action of the first acting force and the second acting force; and

the micro-element located at the target position is recycled.

In the micro-element recycling method, the micro-elements, for example, the red, green and blue mixed LED chips are collected, then the micro-elements are horizontally moved by means of the equal second acting force, and owing to the different masses of the micro-elements, required times of the micro-elements entering a collection device are different, such that the micro-elements have different movement distances in a horizontal direction, so as to separate the micro-elements of different types.

In an embodiment, the step of collecting at least one micro-element failing in transfer includes:

a first collection device is placed in a container in which self-assembly transfer is performed;

a third acting force is applied to the micro-element in a third direction; and

the micro-element failing in transfer is attached to a surface of one side of the first collection device by means of the third acting force.

In an embodiment, the step of applying a first acting force to the micro-element in a first direction includes:

the micro-element is arranged at a preset height to make gravity of the micro-element serve as the first acting force; or,

the first acting force with a direction different from the second direction and the gravity direction of the micro-element is applied on the micro-element.

In an embodiment, the step of applying a second acting force to the micro-element in a second direction includes:

an electric field force is applied in the second direction of the micro-element; or a Lorentz force is applied in the second direction of the micro-element.

In an embodiment, the step of applying an electric field force in the second direction of the micro-element includes:

a charge is added to the micro-element; and

the micro-element with the charge is arranged in a preset electric field.

In an embodiment, the step of applying a Lorentz force in the second direction of the micro-element includes:

a charge is added to the micro-element; and

the micro-element with the charge is arranged in a preset magnetic field.

In an embodiment, the step of recycling the micro-element located at the target position includes:

a second collection device is placed at the target position;

at least one collection tank is provided on the second collection device; and

the micro-element is recycled via the collection tank.

In an embodiment, the micro-element recycling method further includes:

at least a closed or non-closed insulation space is provided, and in the insulation space, the micro-element is moved from the initial position to the target position by means of the first acting force and the second acting force.

Based on the same inventive concept, the present disclosure further provides a micro-element recycling system, including a first collection device, a second acting force applying device and a second collection device;

wherein the first collection device is configured to collect at least one micro-element failing in transfer;

the second acting force applying device is configured to apply a second acting force in a second direction of the micro-element; and

after the micro-element is moved from an initial position to a target position by means of the combined action of a first acting force and the second acting force, the second collection device is configured to collect and recycle the micro-element located at the target position.

In the micro-element recycling system, the micro-elements, for example, the red, green and blue mixed LED chips are collected by means of the first collection device, then the micro-elements are subjected to the second acting force by means of the second acting force applying device to be horizontally moved, and owing to the different masses of the micro-elements, required times of the micro-elements entering the second collection device are different, such that the micro-elements have different movement distances in a horizontal direction, so as to separate the micro-elements of different types.

In an embodiment, the micro-element recycling system further includes an insulation device, wherein the insulation device is provided with at least a closed or non-closed insulation space, and the micro-element is moved from the initial position to the target position by means of the first acting force and the second acting force in the insulation space.

### BRIEF DESCRIPTION OF THE DRAWINGS

For ease of illustration, the present disclosure is described in detail by the following preferred embodiments and accompanying drawings.

FIG. 1 is a schematic diagram of workflow of one embodiment of a micro-element recycling method of an embodiment of the present disclosure;

FIG. 2 is a schematic diagram of a working principle of S101 of the micro-element recycling method of an embodiment of the present disclosure;

FIG. 3 is a schematic diagram of a working principle of S103 of the micro-element recycling method of an embodiment of the present disclosure;

FIG. 4 is a schematic diagram of a working principle of S105 of the micro-element recycling method of an embodiment of the present disclosure;

FIG. 5 is a schematic diagram of workflow of another embodiment of the micro-element recycling method of an embodiment of the present disclosure; and

FIG. 6 is a schematic diagram of a working principle of S205 of the micro-element recycling method of an embodiment of the present disclosure.

### DETAILED DESCRIPTION OF THE EMBODIMENTS

For making the objectives, technical solutions and advantages of the present disclosure clearer, the present disclosure will be described in further detail below in conjunction with the accompanying drawings and embodiments. It should be understood that the specific embodiments described herein are merely illustrative of the present disclosure and are not intended to limit the present disclosure.

In the description of the present disclosure, it is to be understood that the terms “central”, “longitudinal”, “transverse”, “length”, “width”, “thickness”, “upper”, “lower”, “front”, “back”, “left”, “right”, “vertical”, “horizontal”, “top”, “bottom”, “inner”, “outer”, “clockwise”, “counterclockwise”, etc. indicate orientation or positional relations based on those shown in the drawings only for ease of description of the present disclosure and for simplicity of description, and are not intended to indicate or imply that the referenced device or element must have a particular orientation and be constructed and operative in a particular orientation, and thus may not be construed as a limitation on the present disclosure. In addition, the terms “first”, “second” and so forth are for descriptive purposes only and are not to be construed as indicating or implying their relative importance or implicitly specifying the number of indicated technical features. Thus, a feature defined with “first” and “second” may explicitly or implicitly include at least one of the features. In the description of the present disclosure, “plurality” means two or more, unless expressly specified otherwise.

In the present disclosure, unless expressly specified otherwise, the terms “mount”, “connect”, “connected”, etc. are to be construed broadly and, for example, may be fixedly connected, or detachably connected, or integrally connected, may be mechanically connected, or electrically connected, may be direct connected or indirect connected via an intermediary medium, or may be a communication between two elements or an interworking relation between two elements. The specific meanings of the above terms in the present disclosure may be understood on a case-by-case basis for those of ordinary skill in the art.

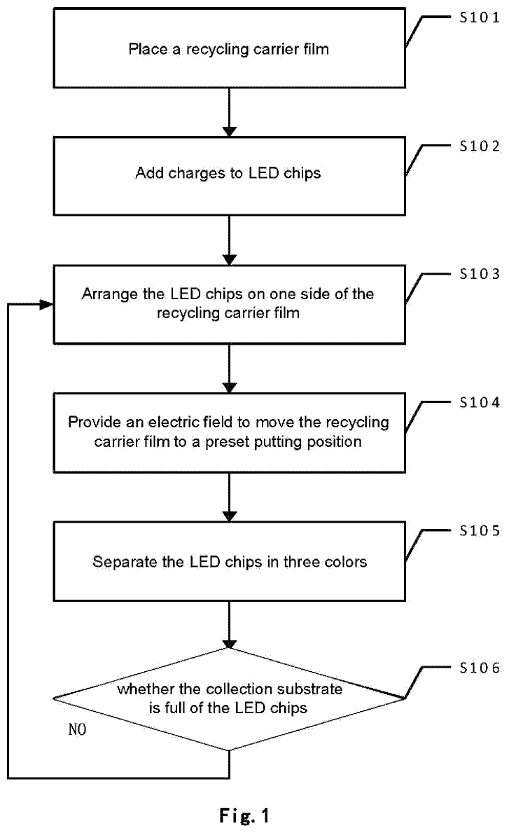

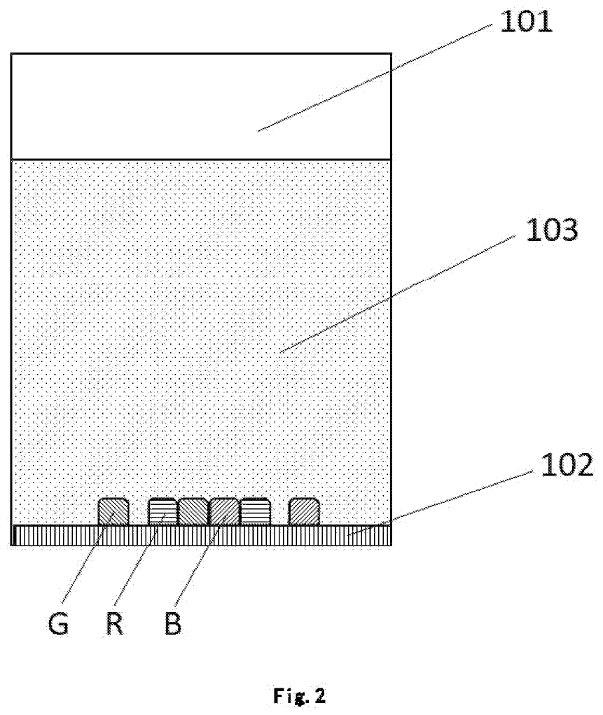

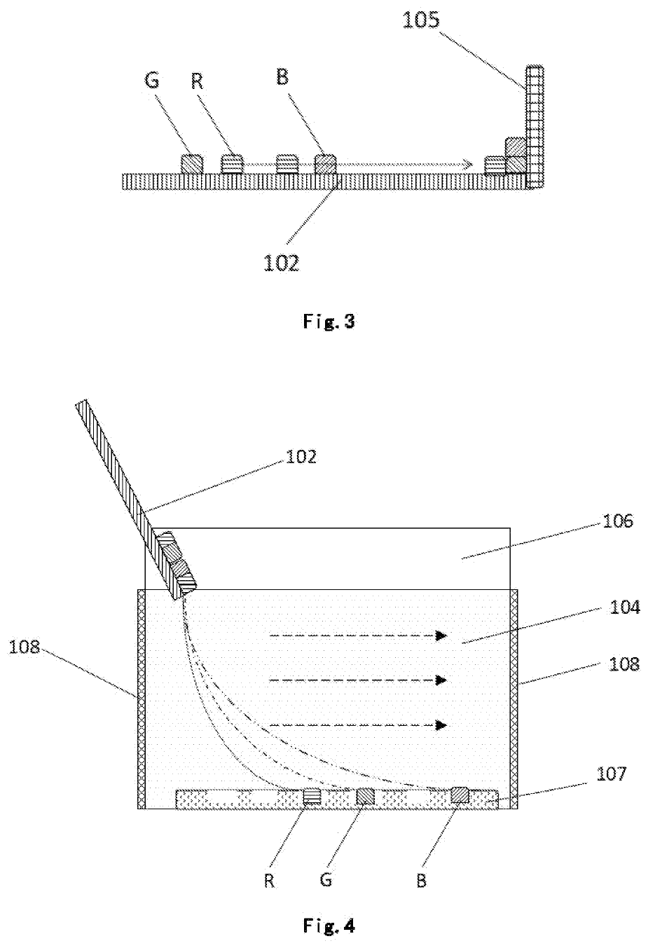

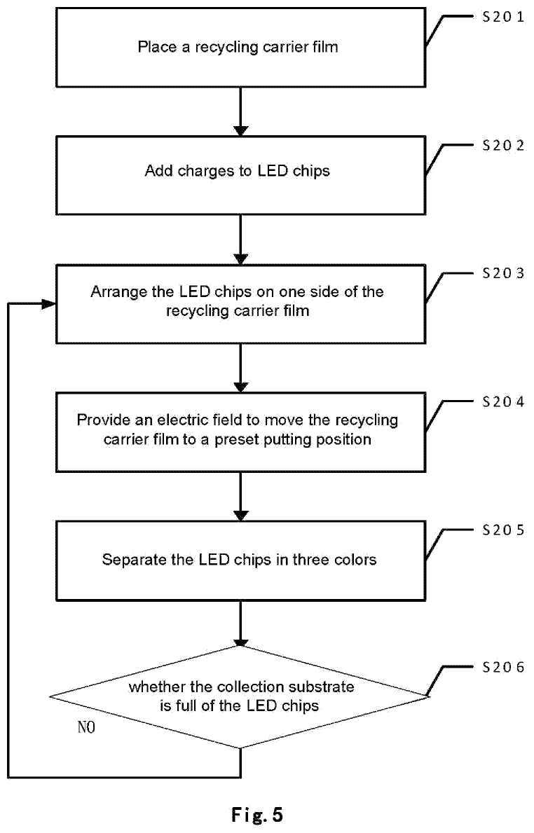

A micro-element recycling method of the present disclosure will now be described in detail in conjunction with one embodiment. With reference to FIGS. 1-4, the method includes:

S101, a recycling carrier film is placed.

A first collection device is placed at a bottom of a transfer container 101, and the first collection device is the recycling carrier film 102, and one or more recycling carrier films 102 may be provided. In this embodiment, the transfer container 101 is a place where plenty of micro-elements are transferred, after transfer fails, the micro-elements fall into the bottom of the transfer container 101, and accordingly, the micro-elements falling into the bottom of the transfer container 101 may be conveniently recycled by placing the recycling carrier film 102 at the bottom of the transfer container 101; and preferably, the micro-elements are light emitting diode (LED) chips, the LED chips are micro LED chips, the transfer container 101 contains a second insulating liquid 103, and the second insulating liquid 103 does not react with the recycling carrier film 102. The recycling carrier film 102 has desirable toughness, buffer capacity and excellent stability. Preferably, the recycling carrier film 102 is a polymer organic membrane; and a surface of the recycling carrier film 102 has slight viscosity, so as to fix the LED chips falling into the recycling carrier film 102 to a certain extent. The LED chips include a red LED chip R, a green LED chip G and a blue LED chip B, and the red LED chip R, the green LED chip G and the blue LED chip B have different masses.

S102, charges are added to the LED chips.

In a normal transfer process, the LED chips move in the second insulating liquid 103 in the transfer container 101 and enter an open slot of a target substrate. However, under the actual condition, part of LED chips may not enter the open slot of the target substrate due to some conditions, causing transfer failure of the LED chips; when the LED chips fails in transfer, the LED chips fall onto the recycling carrier film 102 at the bottom of the transfer container 101 and are randomly distributed on the recycling carrier film 102, and the recycling carrier film 102 fixes, in a bonding manner, the LED chips falling into the recycling carrier film 102; and positive charges or negative charges are added to surfaces of all the LED chips on the recycling carrier film 102 in a friction electrification mode, an induction electrification mode, a contact electrification mode, etc. In this embodiment, the added charges are positive charges, and the charge quantity is q.

S103, the LED chips are arranged on one side of the recycling carrier film.

A baffle 105 is placed at a tail end of one side of the recycling carrier film 102, and the LED chips scattered on the recycling carrier film 102 are moved to the baffle 105 under the action of a third acting force, for example, an electric field force, a magnetic field force, a mechanical force, etc., and are arranged on one side of the recycling carrier film 102. The applied external force needs to be larger than the micro-adhesion force of the recycling carrier film 102 to the LED chips. The LED chips are arranged on one side of the carrier film, such that the LED chips enter the liquid from the same initial position to fall by an identical height, and then the LED chips with three colors may be separated conveniently.

S104, an electric field is applied to move the recycling carrier film to a preset putting position.

The directional electric field is introduced into a recycling container 106, the electric field has a direction parallel to a direction in which the LED chip needs to move horizontally, the direction in which the LED chip needs to move horizontally is a second direction, and an electric field force borne by the LED chip is a second acting force. In this embodiment, a surface of the LED chip is positively charged, such that the LED chip may move in the direction of the electric field under the action of electric field force; and according to a target groove position in a collection substrate 107, the preset putting position of the recycling carrier film 102 is determined. In this embodiment, a horizontal moving distance of the LED chip in a first insulating liquid may be calculated according to mass of the LED chip and the applied electric field force;

The plurality of groove positions for accommodating the LED chips are arranged on the collection substrate 107, and distances between the groove positions and sizes of the groove positions may be set according to actual needs, so the preset putting position of the LED chips may be determined by means of the target groove positions; and after the preset putting position is determined, the recycling carrier film 102 is moved to the preset putting position of the recycling container 106, and the recycling container 106 contains the first insulating liquid 104, where the recycling carrier film 102 is soluble in the first insulating liquid 104.

S105, the LED chips in three colors are separated.

The baffle 105 at the tail end of the recycling carrier film 102 is moved away to make all the LED chips on the recycling carrier film 102 sequentially slide into the first insulating liquid 104, where the recycling carrier film 102 is soluble in the first insulating liquid 104. In this embodiment, since the recycling carrier film 102 is soluble in the first insulating liquid 104, process steps may be reduced and the efficiency may be improved in the subsequent recycling and classification processes.

The LED chips horizontally move under the action of the electric field force and fall onto a second collection device at the bottom of the recycling container 106 under the action of gravity, where the second collection device is the collection substrate 107. The LED chips falling into the first insulating liquid 104 move in the horizontal direction under the action of the electric field force, since the red, green and blue LED chips have different masses, the gravities borne by the LED chips are different, the gravities are the first acting force borne by the LED chips, and an acting direction of the gravities is the first direction and is vertically downward specifically; and therefore, the LED chips with different colors of red, green and blue fall to the bottom for different times, so movement distances in the horizontal direction are different, and the red, green and blue LED chips are separated due to reaching different target position when falling to the bottom. Since the separated red, green and blue LED chips have the charges, the LED chips may be transferred again by directly using a liquid self-assembly mode driven by an electric field or a magnetic field.

S106, it is determined whether the collection substrate is full of the LED chips.

Whether all the groove positions on the collection substrate 107 accommodate the LED chips is determined, if not, a new recycling carrier film 102 with the LED chips fixed in a bonding manner is obtained again, and S103 is performed, the LED chips are arranged on one side of the recycling carrier film 102.

In this embodiment, the electric field is applied in the recycling container, so the micro LED chips in three colors horizontally move under the action of the electric field force, and since the micro LED chips in three colors have different masses, the time for falling to the bottom of the container is different, and the movement distances of the micro LED chips in the horizontal direction are different, thereby effectively separating the micro LED chips in three colors.

In another embodiment, the collection substrate 107 may be arranged at an upper end of the recycling container 106, and the first force is applied in the recycling container 106, the first force being opposite the gravity in direction, and the first force being larger than the gravity; and therefore, the micro-element may overcome the gravity to move upwards under the action of the first acting force, and is driven by the electric field force to move horizontally, so as to enter the collection substrate 107 at the upper end of the recycling container 106. The first acting force may be buoyancy force, wind force, etc.

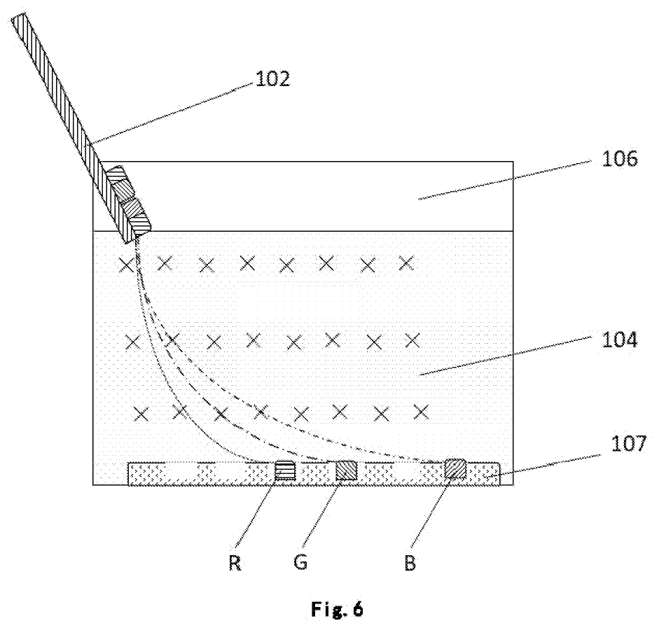

A micro-element recycling method of the present disclosure will now be described in detail in conjunction with another embodiment. With reference to FIGS. 5-6, the method includes:

S201, a recycling carrier film is placed.

The recycling carrier film 102 is placed at a bottom of a transfer container 101, where one or more recycling carrier films 102 may be provided. In this embodiment, the transfer container 101 is a place where plenty of micro-elements are transferred, after transfer fails, the micro-elements fall into the bottom of the transfer container 101, and accordingly, the micro-elements falling into the bottom of the transfer container 101 may be conveniently recycled by placing the recycling carrier film 102 at the bottom of the transfer container 101; and preferably, the micro-elements are LED chips, the transfer container 101 contains a second insulating liquid 103, and the second insulating liquid 103 does not react with the recycling carrier film 102. The recycling carrier film 102 has desirable toughness, buffer capacity and excellent stability. Preferably, the recycling carrier film 102 is a polymer organic membrane; and a surface of the recycling carrier film 102 has slight viscosity, so as to fix the LED chips falling into the recycling carrier film 102 to a certain extent.

S202, charges are added to the LED chips.

In a normal transfer process, the LED chips move in the second insulating liquid 103 in the transfer container 101 and enter an open slot of a target substrate. However, under the actual condition, part of LED chips may not enter the open slot of the target substrate due to some conditions, causing transfer failure of the LED chips; when the LED chips fails in transfer, the LED chips fall onto the recycling carrier film 102 at the bottom of the transfer container 101 and are randomly distributed on the recycling carrier film 102, and the recycling carrier film 102 fixes, in a bonding manner, the LED chips falling into the recycling carrier film 102; and positive charges or negative charges are added to surfaces of all the LED chips on the recycling carrier film 102 in a friction electrification mode, an induction electrification mode, a contact electrification mode, etc. In this embodiment, the added charges are positive charges, and the charge quantity is q, the LED chips include a red LED chip R, a green LED chip G and a blue LED chip B, and the red LED chip R, the green LED chip G and the blue LED chip B have different masses.

S203, the LED chips are arranged on one side of the recycling carrier film.

A baffle 105 is placed at a tail end of one side of the recycling carrier film 102, and the LED chips scattered on the recycling carrier film 102 are moved to the baffle 105 under the action of a third acting force, for example, an electric field force, a magnetic field force, a mechanical force, etc., and are arranged on one side of the recycling carrier film 102. The applied external force needs to be larger than the micro-adhesion force of the recycling carrier film 102 to the LED chips. The LED chips are arranged on one side of the carrier film, such that the LED chips enter the liquid from the same position to fall by an identical height, and then the LED chips with three colors may be separated conveniently.

S204, a magnetic field is applied to move the recycling carrier film to a preset putting position.

The directional magnetic field is introduced into a recycling container 106, the magnetic field has a direction perpendicular to a direction in which the LED chip needs to move horizontally, the direction in which the LED chip needs to move horizontally is a second direction, and a Lorentz force borne by the LED chip is a second acting force. In this embodiment, a surface of the LED chip is positively charged, such that the LED chip may move in the horizontal direction under the action of Lorentz force; and according to a target groove position in a collection substrate 107, the preset putting position of the recycling carrier film 102 is determined. In this embodiment, a horizontal moving distance of the LED chip in a first insulating liquid 104 may be calculated according to mass of the LED chip and the applied electric field force;

The plurality of groove positions for accommodating the LED chips are arranged on the collection substrate 107, and distances between the groove positions and sizes of the groove positions may be set according to actual needs, so the preset putting position of the LED chips may be determined by means of the target groove positions; and after the preset putting position is determined, the recycling carrier film 102 is moved to the preset putting position of the recycling container 106, and the recycling container 106 contains the first insulating liquid 104, where the carrier film is soluble in the first insulating liquid 104. In this embodiment, since the recycling carrier film 102 is soluble in the first insulating liquid 104, process steps may be reduced and the efficiency may be improved in the subsequent recycling and classification processes.

S205, the LED chips in three colors are separated.

The baffle 105 at the tail end of the recycling carrier film 102 is moved away to make all the LED chips on the recycling carrier film 102 sequentially slide into the first insulating liquid 104, where the recycling carrier film 102 is soluble in the first insulating liquid 104. In this embodiment, since the recycling carrier film 102 is soluble in the first insulating liquid 104, process steps may be reduced and the efficiency may be improved in the subsequent recycling and classification processes.

The LED chips horizontally move under the action of the Lorentz force and fall onto the collection substrate 107 at the bottom of the recycling container 106 under the action of gravity. The LED chips falling into the first insulating liquid 104 move in the horizontal direction under the action of the Lorentz force, since the red, green and blue LED chips have different masses, the gravities borne by the LED chips are different, the gravities are the first acting force borne by the LED chips, and an acting direction of the gravities is the first direction and is vertically downward specifically; and therefore, the LED chips with different colors of red, green and blue fall to the bottom for different times, so movement distances in the horizontal direction are different, and the red, green and blue LED chips are separated due to reaching different position when falling to the bottom. Since the separated red, green and blue LED chips have the charges, the LED chips may be transferred again by directly using a liquid self-assembly mode driven by an electric field or a magnetic field.

S206, it is determined whether the collection substrate is full of the LED chips.

Whether all the groove positions on the collection substrate 107 accommodate the LED chips is determined, if not, a new recycling carrier film 102 with the LED chips fixed in a bonding manner is obtained again, and S203 is performed, the LED chips are arranged on one side of the carrier film.

In this embodiment, the magnet field is applied in the recycling container, so the micro LED chips in three colors horizontally move under the action of the Lorentz force, and since the micro LED chips in three colors have different masses, the time for falling to the bottom of the container is different, and the movement distances of the micro LED chips in the horizontal direction are different, thereby effectively separating the micro LED chips in three colors.

In another embodiment, the collection substrate 107 may be arranged at an upper end of the recycling container 106, and the first force is applied in the recycling container 106, the first force being opposite the gravity in direction, and the first force being larger than the gravity; and therefore, the micro-element may overcome the gravity to move upwards under the action of the first acting force, and is driven by the Lorentz force to move horizontally, so as to enter the collection substrate 107 at the upper end of the recycling container 106. The first acting force may be buoyancy force, wind force, etc.

A micro-element recycling system of the present disclosure will now be described in detail in conjunction with an embodiment, and the system includes: a first collection device, a second acting force applying device and a second collection device.

The first collection device collects at least one micro-element failing in transfer. In this embodiment, the first collection device is a recycling carrier film.

The second acting force applying device applies a second acting force in a second direction of the micro-element; the second acting force applying device may be an electric field generator or a magnetic field generator, when the second acting force applying device is the electric field generator, the second acting force borne by the micro-element is an electric field force, and the second direction is parallel to a direction of an electric field; and when the second acting force applying device is the magnetic field generator, the second acting force borne by the micro-element is a Lorentz force, and the second direction is perpendicular to a direction of a magnetic field; and

After the micro-element is subjected to the combined action of a first acting force and the second acting force, the micro-element is moved from an initial position to a target position, and the second collection device collects and recycles the micro-element located at the target position. In this embodiment, the first acting force may be gravity, and may also be buoyancy force, wind force, etc. for overcoming the gravity to do work by the micro-element; and the second collection device is a collection substrate.

In another embodiment, the micro-element recycling system may further include: a first acting force applying device for applying a first acting force to a micro-element.

In an embodiment, the micro-element recycling system further includes an insulation device,

where the insulation device is provided with at least a closed or non-closed insulation space, and the micro-element is moved from the initial position to the target position by means of the first acting force and the second acting force in the insulation space. The insulation device includes a recycling container, and an insulating liquid is contained in the recycling container.

In the description of this specification, reference terms “one embodiment”, “some embodiments”, “an illustrative embodiment”, “an example”, “a specific example”, or “some examples”, etc., mean that a particular feature, structure, material, or characteristic described in conjunction with the embodiment or example is included in at least one embodiment or example of the present disclosure. In the present specification, schematic expressions of the above terms do not necessarily refer to the same embodiment or example. Furthermore, the particular features, structures, materials, or characteristics described may be combined in a suitable manner in any one or more embodiments or examples.

The above-mentioned are merely preferred embodiments of the present disclosure, and are not intended to limit the present disclosure. Any modifications, equivalent replacements and improvements made within the spirit and principle of the present disclosure should fall within the protection scope of the present disclosure.

1. A micro-element recycling method, comprising:
collecting at least one micro-element failing in transfer;
applying a first acting force to the micro-element in a first direction, and applying a second acting force to the micro-element in a second direction;
moving the micro-element from an initial position to a target position by means of the combined action of the first acting force and the second acting force; and
recycling the micro-element located at the target position.

2. The micro-element recycling method according to claim 1, wherein the collecting at least one micro-element failing in transfer comprises:
placing a first collection device in a container in which self-assembly transfer is performed;
applying a third acting force to the micro-element in a third direction; and
attaching the micro-element failing in transfer to a surface of one side of the first collection device by means of the third acting force.

3. The micro-element recycling method according to claim 1, wherein the applying a first acting force to the micro-element in a first direction comprises:
arranging the micro-element at a preset height to make gravity of the micro-element serve as the first acting force; or,
applying the first acting force with a direction different from the second direction and the gravity direction of the micro-element on the micro-element.

4. The micro-element recycling method according to claim 1, wherein applying a second acting force to the micro-element in a second direction comprises:
applying an electric field force in the second direction of the micro-element; or
applying a Lorentz force in the second direction of the micro-element.

5. The micro-element recycling method according to claim 4, wherein the applying an electric field force in the second direction of the micro-element comprises:
adding a charge to the micro-element; and
arranging the micro-element with the charge in a preset electric field.

6. The micro-element recycling method according to claim 4, wherein the applying a Lorentz force in the second direction of the micro-element comprises:
adding a charge to the micro-element; and
arranging the micro-element with the charge in a preset magnetic field.

7. The micro-element recycling method according to claim 1, wherein the recycling the micro-element located at the target position comprises:
placing a second collection device at the target position;
providing at least one collection tank in the second collection device; and
recycling the micro-element via the collection tank.

8. The micro-element recycling method according to claim 1, further comprising:
providing at least a closed or non-closed insulation space, and in the insulation space, moving the micro-element from the initial position to the target position by means of the first acting force and the second acting force.

9. A micro-element recycling system, comprising a first collection device, a second acting force applying device and a second collection device; wherein
the first collection device is configured to collect at least one micro-element failing in transfer;
the second acting force applying device is configured to apply a second acting force in a second direction of the micro-element; and
after the micro-element is moved from an initial position to a target position by means of the combined action of a first acting force and the second acting force, the second collection device is further configured to collect and recycle the micro-element located at the target position.

10. The micro-element recycling system according to claim 9, further comprising an insulation device, wherein the insulation device is provided with at least a closed or non-closed insulation space, and in the insulation space, the micro-element is moved from the initial position to the target position by means of the first acting force and the second acting force.

11. The micro-element recycling system according to claim 9, further comprising a third acting force applying device, wherein the first collection device is placed in a container in which self-assembly transfer is performed, and the third acting force applying device is configured to apply a third acting force to the micro-element in a third direction, so as to attach the micro-element failing in transfer to a surface of one side of the first collection device.

12. The micro-element recycling system according to claim 9, wherein the micro-element is arranged at a preset height to make gravity of the micro-element serve as the first acting force; or,
the first acting force applied on the micro-element is in a direction different from the second direction and the gravity direction of the micro-element.

13. The micro-element recycling system according to claim 9, wherein the second acting force is an electric field force applied in the second direction of the micro-element, the second acting force is a Lorentz force applied in the second direction of the micro-element.

14. The micro-element recycling system according to claim 13, the micro-element with a charge in a preset electric field.

15. The micro-element recycling system according to claim 13, wherein the micro-element with a charge is arranged in a preset magnetic field.

16. The micro-element recycling system according to claim 9, further comprising a second collection device, wherein the second collection device is placed at the target position, and at least one collection tank is provided in the second collection device to recycle the micro-element.
